(19) United States
(12) Patent Application Publication
(10) Pub. No.: US 2025/0194343 A1
(43) Pub. Date: Jun. 12, 2025

(54) DISPLAY PANEL, PREPARATION METHOD THEREOF, AND DISPLAY DEVICE

(71) Applicants: Hefei Visionox Technology Co., Ltd., Hefei (CN); KunShan Go-Visionox Opto-Electronics Co., Ltd, Kunshan (CN)

(72) Inventors: Zhiwei ZHOU, Kunshan (CN); Jinfang ZHANG, Kunshan (CN); Lu ZHANG, Kunshan (CN)

(73) Assignees: Hefei Visionox Technology Co., Ltd., Hefei (CN); KunShan Go-Visionox Opto-Electronics Co., Ltd, Kunshan (CN)

(21) Appl. No.: 18/655,661

(22) Filed: May 6, 2024

(30) Foreign Application Priority Data
Dec. 8, 2023 (CN) 202311694025.1

(51) Int. Cl. H10K 59/122; H10K 59/35; H10K 59/80

(52) U.S. Cl. CPC H10K 59/122; H10K 59/352; H10K 59/805

(57) ABSTRACT

A display panel, a preparation method thereof, and a display device. The display panel includes a substrate, a first electrode, an auxiliary electrode, a pixel defining layer, and an isolation structure. The first electrode is disposed on a side of the substrate. The auxiliary electrode is at least in contact with an edge of the first electrode. The pixel defining layer is provided with multiple first openings exposing the auxiliary electrode and/or the first electrode. The isolation structure includes a second opening. The vertical projection of the first electrode on the substrate is disposed within the vertical projection of the second opening on the substrate.

### CROSS-REFERENCE TO RELATED APPLICATION

This application claims priority to Chinese patent application No. 202311694025.1 filed Dec. 8, 2023, the disclosure of which is incorporated herein by reference in its entirety.

### TECHNICAL FIELD

Embodiments of the present disclosure relate to the field of display technologies, in particular, a display panel, a preparation method thereof, and a display device.

### BACKGROUND

With the development of display technologies, people have increasingly higher requirements for display quality.

However, display panels in the related art are prone to the problem of poor display effect during display, which limits further applications of display panels.

### SUMMARY

Embodiments of the present disclosure provide a display panel, a preparation method thereof, and a display device to improve the display effect of the display panel.

Embodiments of the present disclosure provide a display panel. The display panel includes a substrate, a first electrode, an auxiliary electrode, a pixel defining layer, and an isolation structure.

The first electrode is disposed on a side of the substrate. The auxiliary electrode is at least in contact with an edge of the first electrode. The auxiliary electrode is configured to provide an electrical signal to the first electrode. The pixel defining layer is provided with multiple first openings exposing the auxiliary electrode and/or the first electrode.

The isolation structure is disposed on a side of the pixel defining layer facing away from the substrate. The isolation structure is provided with a second opening. A vertical projection of the first electrode on the substrate is disposed within a vertical projection of the second opening on the substrate.

Embodiments of the present disclosure provide a method for preparing the display panel. The method includes the steps below.

A substrate is provided.

A first electrode, an auxiliary electrode, and a pixel defining layer are formed on the substrate, where the auxiliary electrode is at least in contact with an edge of the first electrode, and the pixel defining layer is provided with multiple first openings exposing the auxiliary electrode and/or the first electrode.

An isolation structure is formed on a side of the pixel defining layer facing away from the substrate. The isolation structure is provided with a second opening. A vertical projection of the first electrode on the substrate is disposed within a vertical projection of the second opening on the substrate.

Embodiments of the present disclosure provide a display device. The device includes the display panel provided by any embodiment of the present disclosure.

In the technical scheme provided by the embodiment of the present disclosure, the display panel includes a substrate, a first electrode, an auxiliary electrode, a pixel defining layer, and an isolation structure. The first electrode is disposed on a side of the substrate. The auxiliary electrode is at least in contact with an edge of the first electrode. The auxiliary electrode is configured to provide an electrical signal to the first electrode. The pixel defining layer is provided with multiple first openings exposing the auxiliary electrode and/or the first electrode. The isolation structure is provided with a second opening. The vertical projection of the first electrode on the substrate is disposed within the vertical projection of the second opening on the substrate. In this scheme, the first electrode is limited within the second opening enclosed by the isolation structure, and an electrical signal is provided to the first electrode through the auxiliary electrode. In this manner, no edge of the first electrode exists under the isolation structure, thereby improving the flatness of the pixel defining layer and isolation structure.

### BRIEF DESCRIPTION OF DRAWINGS

FIG. 1 is a diagram illustrating the structure of a display panel according to an embodiment of the present disclosure.

FIG. 2 is a diagram illustrating the structure of another display panel according to an embodiment of the present disclosure.

FIG. 3 is a top view of the structure of a display panel according to an embodiment of the present disclosure.

FIG. 4 is a diagram illustrating the structure of another display panel according to an embodiment of the present disclosure.

FIG. 5 is a diagram illustrating the structure of another display panel according to an embodiment of the present disclosure.

FIG. 6 is a diagram illustrating the structure of another display panel according to an embodiment of the present disclosure.

FIG. 7 is a diagram illustrating the structure of another display panel according to an embodiment of the present disclosure.

FIG. 8 is a diagram illustrating the structure of another display panel according to an embodiment of the present disclosure.

FIG. 9 is a flowchart of a method for preparing a display panel according to an embodiment of the present disclosure.

FIG. 10 is a diagram illustrating the structure of a display panel formed by the main steps of the method for preparing a display panel according to an embodiment of the present disclosure.

FIG. 11 is a diagram illustrating the structure of a display device according to an embodiment of the present disclosure.

### DETAILED DESCRIPTION

It is to be noted that terms such as “first” and “second” in the description, claims, and drawings of the present disclosure are used to distinguish between similar objects and are not necessarily used to describe a particular order or sequence. It should be understood that the data used in this manner are interchangeable where appropriate so that the embodiment of the present disclosure described herein may also be implemented in a sequence not illustrated or described herein. Additionally, terms “comprising”, “including”, and any other variations thereof are intended to encompass a non-exclusive inclusion. For example, a process, method, system, product, or device that includes a series of steps or units not only includes the expressly listed steps or units but may also include other steps or units that are not expressly listed or are inherent to such a process, method, product, or device.

As described in the background, display panels in the related art are prone to the problem of of poor display effects. After careful study, the inventor finds that the reason for the preceding problem is as follows: In display panels using sample pixel-level packaging schemes, a pixel light-emitting region is usually defined by a pixel defining layer, and the pixel defining layer covers the surface of the anode. However, due to the existence of the anode metal boundary, the surface of the pixel defining layer is uneven. When an isolation structure is formed on the pixel defining layer, the surface of the isolation structure is also uneven, which causes deviations in the side etching of the isolation structure and thus affects the stability of evaporation shadows. Moreover, a deviation occurs during the evaporation of the cathode, which affects the overlap and contact between the cathode and the isolation structure, brings the undesirable phenomenon of large areas of dark spots, thereby reducing the display effect.

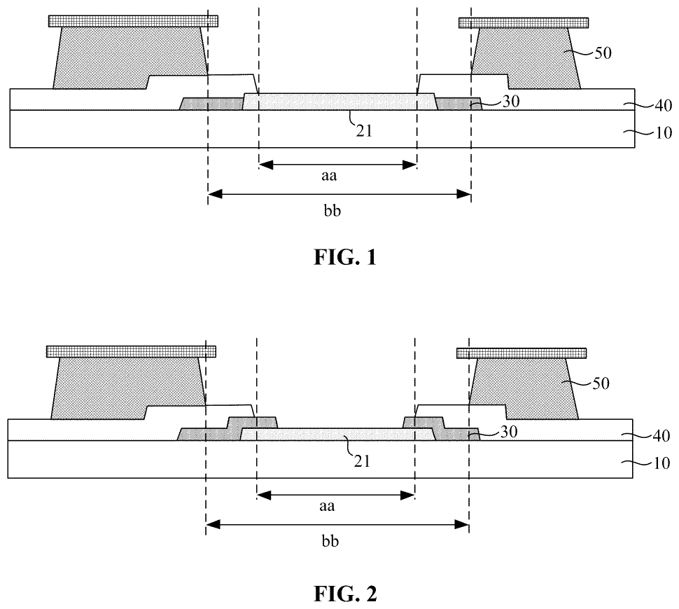

In view of the preceding problems, an embodiment of the present disclosure provides a display panel. FIG. 1 is a diagram illustrating the structure of a display panel according to an embodiment of the present disclosure. FIG. 2 is a diagram illustrating the structure of another display panel according to an embodiment of the present disclosure. With reference to FIGS. 1 and 2, the display panel provided by this embodiment includes a substrate 10, a first electrode 21, an auxiliary electrode 30, a pixel defining layer 40, and an isolation structure 50.

The first electrode 21 is disposed on a side of the substrate 10. The auxiliary electrode 30 is at least in contact with an edge of the first electrode 21. The auxiliary electrode 30 is configured to provide an electrical signal to the first electrode 21. The pixel defining layer 40 is provided with multiple first openings exposing the auxiliary electrode 30 or the first electrode 21.

The isolation structure 50 is disposed on a side of the pixel defining layer 40 facing away from the substrate 10. The isolation structure 50 is provided with a second opening. The vertical projection of the first electrode 21 on the substrate 10 is disposed within the vertical projection of the second opening on the substrate.

In an embodiment, the substrate 10 may be a rigid substrate, such as a glass substrate; the substrate 10 may also be a flexible substrate, such as a polyimide (PI) substrate. A pixel circuit array is disposed on the substrate 10. A pixel circuit is used to drive a light-emitting element for display.

A first electrode 21, an auxiliary electrode 30, and a pixel defining layer 40 are formed on the substrate 10. The pixel defining layer 40 is configured to define a pixel region. The pixel defining layer 40 includes the first opening exposing the auxiliary electrode 30 and/or the first electrode 21. As shown in the figures, the region aa is the region where the first opening is disposed. The auxiliary electrode 30 is at least in contact with the edge of the first electrode 21. The first electrode 21 and the auxiliary electrode 30 are configured to transmit an electric signal (such as a voltage signal or current signal). In this embodiment, the first electrode 21 may be an anode of a light-emitting element; the light-emitting element further includes a light-emitting functional layer and a cathode (not shown in the figures). Here, the auxiliary electrode 30 is at least in contact with the edge of the first electrode 21, which indicates that the auxiliary electrode 30 overlaps and contacts the edge of the first electrode 21. Illustratively, the auxiliary electrode 30 may cover the edge of the first electrode 21.

The isolation structure 50 is formed on the side of the pixel defining layer 40 facing away from the substrate 10. The isolation structure 50 may be used to isolate multiple pixel units. Here, the second opening is formed by the enclosure of the isolation structure 50. As shown in FIG. 1, the bb region is the region where the second opening is disposed. The second opening may be understood as an opening enclosed by a side of the isolation structure 50 in contact with the pixel defining layer 40.

In this embodiment, the vertical projection of the first electrode 21 on the substrate 10 is disposed within the vertical projection of the second opening on the substrate 10. The projection of the second opening may be understood as a vertical projection region of the opening space enclosed by the isolation structure 50 on the substrate 10. That is, the first electrode 21 is disposed in the second opening. In other words, the first electrode 21 is disposed in an enclosed region of the isolation structure 50. An edge of the first electrode 21 does not overlap the vertical projection of the surface of the isolation structure 50 in contact with the substrate 10 on the substrate 10, and the first electrode 21 does not exist below the isolation structure 50 so that the flatness of the position of the pixel defining layer 40 corresponding to the isolation structure 50 can be improved. Moreover, when the isolation structure 50 is subsequently formed, the flatness of the isolation structure 50 can be improved.

It should be noted that in the related art, an edge of the first electrode 21 is disposed below the isolation structure 50, and the first electrode 21 is connected to the pixel circuit on the substrate 10 through a via so that an electric signal is provided to the first electrode 21 through the pixel circuit. In this embodiment, since the first electrode 21 is limited within the second opening enclosed by the isolation structure 50, the length of the first electrode 21 in the direction perpendicular to the thickness of the display panel is reduced. Moreover, the via used to connect the pixel circuit cannot be too close to the pixel region. Therefore, in order to ensure that the voltage signal is able to be transmitted to the first electrode 21, an auxiliary electrode 30 is provided in this embodiment, and the auxiliary electrode 30 overlaps and contacts the first electrode 21 so that the voltage signal is transmitted to the first electrode 21 through the auxiliary electrode 30.

In the technical scheme provided by the embodiment of the present disclosure, the display panel includes a substrate, a first electrode, an auxiliary electrode, a pixel defining layer, and an isolation structure. The first electrode is disposed on a side of the substrate. The auxiliary electrode is at least in contact with an edge of the first electrode. The auxiliary electrode is configured to provide an electrical signal to the first electrode. The pixel defining layer is provided with multiple first openings exposing the auxiliary electrode and/or the first electrode. The isolation structure is provided with a second opening. The vertical projection of the first electrode on the substrate is disposed within the vertical projection of the second opening on the substrate. In this scheme, the first electrode is limited within the second opening enclosed by the isolation structure, and an electrical signal is provided to the first electrode through the auxiliary electrode. In this manner, no edge of the first electrode exists under the isolation structure, thereby improving the flatness of the pixel defining layer and isolation structure, helping improve the overlapping and contacting effect between the isolation structure and the cathode in a light-emitting element, and preventing dark spots caused by poor overlapping and contacting. In addition, by limiting the first electrode, the gap in the pixel defining layer can be further reduced to prevent the occurrence of mixed colors or color spots.

In this embodiment, the pixel defining layer 40 includes an inorganic material. The inorganic material has good hydrophobic properties so that when water and oxygen enter a certain pixel region and cause a corresponding pixel unit to fail, the water and oxygen are prevented from extending along the pixel defining layer 40 to adjacent pixel regions, thereby reducing adverse effects on pixel units in the adjacent pixel regions. In addition, the inorganic materials have poor flatness. Therefore, the flatness of the pixel defining layer 40 can be improved by using the technical scheme provided in this embodiment, thereby improving the flatness of the isolation structure.

In an embodiment, the second opening may be connected to the first opening, the second opening exposes the first opening and at least part of the pixel defining layer 40, and the first opening is disposed in the second opening.

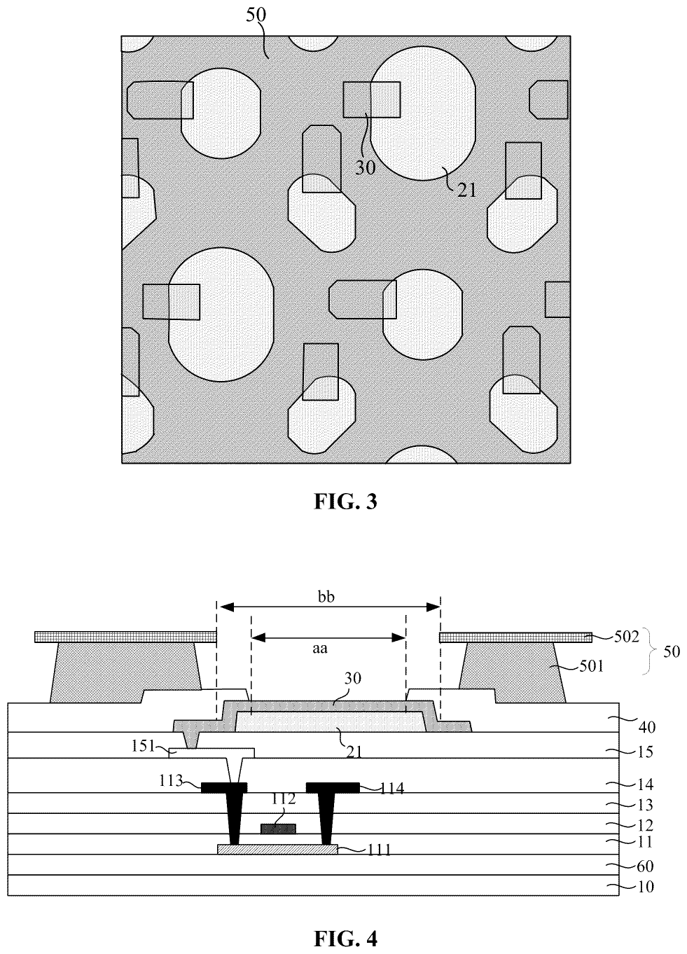

FIG. 3 is a top view of the structure of a display panel according to an embodiment of the present disclosure. With reference to FIG. 3, the first electrode 21 is oval or oval-like, and it can be clearly seen from the top view that the first electrode 21 is disposed in the second opening formed by the isolation structure 50, the first electrode 21 does not overlap the isolation structure 50, and the auxiliary electrode 30 contacts the first electrode 21 and is connected to a lower conductive layer through a via (for example, the auxiliary electrode 30 is connected to a lower pixel circuit). Here, the isolation structure 50 is a full-surface structure, and the first electrode 21 and part of the auxiliary electrode 30 are exposed by digging holes. With reference to FIG. 1, the auxiliary electrode 30 is disposed on a side of the first electrode 21 facing away from the substrate 10, and the isolation structure 50 is disposed on a side of the auxiliary electrode 30 facing away from the substrate 10.

FIG. 4 is a diagram illustrating the structure of another display panel according to an embodiment of the present disclosure. With reference to FIG. 4, in an embodiment, the vertical projection of the auxiliary electrode 30 on the substrate 10 covers the vertical projection of the first electrode 21 on the substrate 10, and the first opening included in the pixel defining layer 40 exposes the auxiliary electrode 30. The purpose of this configuration is to reduce the number of masks and the number of etchings, thereby simplifying the process. The auxiliary electrode 30 is disposed on a side of the first electrode 21 facing away from the substrate 10 so that the auxiliary electrode 30 covers the first electrode 21. In this manner, the first electrode 21 is protected from being damaged by the preparation process of the auxiliary electrode 30, which is conducive to improving the integrity of the first electrode 21.

The vertical projection of the pixel defining layer 40 on the substrate 10 partially overlaps the vertical projection of the first electrode 21 on the substrate 10 so that the pixel defining layer 40 can define a pixel region. Since the pixel region has certain requirements for the aperture ratio, the first electrode 21 cannot be indefinitely limited within the second opening and should be limited within requirements of the aperture ratio to avoid reducing the display quality. In an embodiment, in the plane parallel to the substrate 10, the width of an overlapping portion between the pixel defining layer 40 and the first electrode 21 is 1 μm to 1.5 μm, and the width of the first opening is 10 μm to 30 μm.

In addition, in the plane parallel to the substrate 10 in this embodiment, the width of a portion of the pixel defining layer 40 disposed between two adjacent first openings is greater than or equal to 8 μm. The first electrode 21 is limited within the second opening so that the first electrode 21 does not exist below the isolation structure 50, and the gap in the pixel defining layer can be further reduced. For example, the width of a portion of the pixel defining layer 40 disposed between two adjacent first openings may be limited to a range of 8 μm to 14 μm to prevent the occurrence of mixed colors or color spots.

With continued reference to FIG. 4, the display panel further includes multiple pixel circuits, the pixel circuit is disposed on a side of the first electrode 21 facing the substrate 10, and the auxiliary electrode 30 is connected to the pixel circuit through a via.

In an embodiment, the pixel circuit includes a first active layer 111, a first gate 112, a first source 114, and a first drain 113.

The first active layer 111 is disposed on a side of the substrate 10.

The first gate 112 is disposed on a side of the first active layer 111 facing away from the substrate 10.

The first source 114 and the first drain 113 are disposed on a side of the first gate 112 facing away from the substrate 10, and the first source 114 and the first drain 113 are connected to a source region and a drain region of the first active layer 111, respectively.

A buffer layer 60 is disposed between the substrate 10 and the first active layer 111. The buffer layer 60 may be made of an inorganic material and plays a role of protection and buffering. A first gate insulating layer 11 is disposed between the first active layer 111 and the first gate 112. The first gate insulating layer 11 covers the first active layer 111 and contacts the buffer layer 60 to insulate the first active layer 111 from the first gate 112. A capacitive dielectric layer 12 is disposed on a side of the first gate 112 facing away from the substrate 10. The capacitive dielectric layer 12 is configured to insulate an upper plate from a lower plate (the upper plate and the lower plate of the capacitor are not shown in the figure) of a storage capacitor. The lower plate of the capacitor may be disposed on the same layer as the first gate 112. A first interlayer insulating layer 13 is disposed on a side of the capacitive dielectric layer 12 facing away from the substrate 10. The first source 114 and the first drain 113 are formed on a side of the first interlayer insulating layer 13 facing away from the substrate 10 and are connected to the first active layer 111 through a via. A first planarization layer 14 covers the first source 114 and the first drain 113. A transfer portion 151 is disposed on a side of the first planarization layer 14 facing away from the substrate 10. The transfer portion 151 is configured to transfer the connection relationship between conductive layers to avoid opening deep holes in the layer structure. A second planarization layer 15 is disposed on a side of the transfer portion 151 facing away from the substrate 10. The first planarization layer 14 and the second planarization layer 15 are configured to flatten the layers for subsequent preparation of light-emitting elements. The auxiliary electrode 30 is connected to the first drain 113 of the pixel circuit through the transfer portion 151 to transmit a drive voltage signal provided by the pixel circuit to the first electrode 21.

With continued reference to FIG. 4, in an embodiment, the vertical projection of the auxiliary electrode 30 on the substrate 10 partially overlaps the vertical projection of the isolation structure 50 on the substrate 10, the auxiliary electrode 30 includes an overlapping portion overlapping the isolation structure 50, and the overlapping portion is connected to the pixel circuit through a via. In this scheme, the auxiliary electrode 30 is used to replace the original first electrode 21 to connect to the pixel circuit. In this manner, the layer structure of the pixel circuit may not be changed, which helps reduce the process difficulty.

In an embodiment, since the auxiliary electrode 30 is used to assist the first electrode 21 to connect to the pixel circuit on the substrate 10, in a thickness direction of the display panel, the thickness of the auxiliary electrode 30 may be less than the thickness of the first electrode 21. When the first electrode 21 is connected to the pixel circuit through the auxiliary electrode 30, even though the auxiliary electrode 21 is disposed below the isolation structure 50, the auxiliary electrode 30 has less influence on the flatness of the upper surface of the pixel defining layer 40 because the thickness of the auxiliary electrode 30 is less than the thickness of the first electrode 21. Compared with the schemes in the related art, the flatness of the isolation structure 50 can be improved in this scheme.

In an embodiment, in this embodiment, in the thickness direction of the display panel, the thickness of the auxiliary electrode 30 is greater than or equal to 0.01 μm and less than or equal to 0.1 μm. If the process conditions permit, the thinner the auxiliary electrode 30 is, the smaller the impact on the flatness of the isolation structure 50 is, and the flatter the isolation structure 50 is.

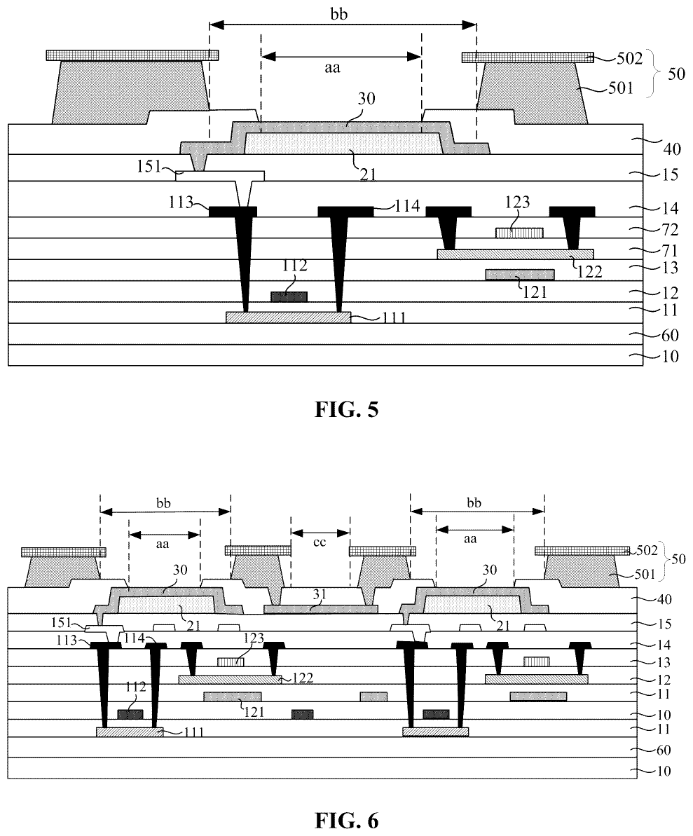

FIG. 5 is a diagram illustrating the structure of another display panel according to an embodiment of the present disclosure. With reference to FIG. 5, based on the preceding technical schemes, in an embodiment, the pixel circuit further includes a second gate 121, a second active layer 122, and a third gate 123. The second active layer 122 is different from the first active layer 111. The material of the second active layer 122 is metal oxide, such as indium gallium zinc oxide. The material of the first active layer 111 is low-temperature polycrystalline silicon.

The second gate 121 may be a bottom gate and is disposed on a side of the capacitive dielectric layer 12 facing away from the substrate 10. The second active layer 122 is disposed on a side of the first interlayer insulating layer 13 facing away from the substrate 10. A second gate insulating layer 71 covers the second active layer 122. The third gate 123 is disposed on a side of the second gate insulating layer 71 facing away from the substrate 10. A second interlayer insulating layer 72 is disposed on a side of the third gate 123 facing away from the substrate 10, and the second interlayer insulating layer 72 covers the third gate 123. The third gate 123 may be a top gate.

With continued reference to FIG. 4 and FIG. 5, in an embodiment, the isolation structure 50 includes a support portion 501 and a crown portion 502; the crown portion 502 is disposed on a side of the support portion 501 facing away from the substrate 10, and the vertical projection of the support portion 501 on the substrate 10 falls within the vertical projection of the crown portion 502 on the substrate 10 so that the isolation structure 50 can isolate the light-emitting functional layers of adjacent light-emitting elements and avoid lateral current crosstalk. In addition, since the isolation structure 50 is in the form of an eaves, the light-emitting functional layer of the light-emitting element in the layer evaporation process can be separately prepared without the use of precision masks, and the light-emitting functional layer of each light-emitting element can be produced by photolithography. Therefore, a precision mask is not required, which can save production costs.

It should be understood that the vertical projection of the surface of the isolation structure 50 facing a side of the substrate 10 on the substrate 10 is disposed within the vertical projection of the surface of the isolation structure 50 facing away from the side of the substrate 10 on the substrate 10. That is, in the direction of the thickness of the display panel, the isolation structure 50 has a structure that is wide at the top and narrow at the bottom, where the support portion 501 may also have a structure that is narrow at the top and wide at the bottom. In an embodiment, the vertical projection of the support portion 501 on the substrate 10 does not overlap the vertical projection of the first electrode 21 on the substrate 10. When the isolation structure 50 includes the support portion 501 and the crown portion 502, the second opening enclosed by the isolation structure 50 is based on a region enclosed by the side of the support portion 501 contacting the pixel defining layer 40. At least the vertical projection of the support portion 501 on the substrate 10 does not overlap the vertical projection of the first electrode 21 on the substrate 10.

In an embodiment, the vertical projection of the crown portion 502 on the substrate 10 does not overlap the vertical projection of the first electrode 21 on the substrate 10. That is, the vertical projection of the entire isolation structure 50 on the substrate 10 does not overlap the vertical projection of the first electrode 21 on the substrate 10. Matching the size of the first opening is beneficial to increase the light-emitting area. Moreover, since the vertical projection of the entire isolation structure 50 on the substrate 10 does not overlap the vertical projection of the first electrode 21 on the substrate 10, not only the flatness of the support portion 501 but also the flatness of the crown portion 502 are improved.

FIG. 6 is a diagram illustrating the structure of another display panel according to an embodiment of the present disclosure. With reference to FIG. 6, based on the preceding technical schemes, in an embodiment, the isolation structure 50 further includes a third opening exposing the pixel defining layer 40, and the second opening is spaced apart from the third opening. As shown in FIG. 6, a cc region is the region where the third opening is disposed. The second opening is an isolation opening configured to accommodate light-emitting elements and isolate adjacent light-emitting elements. The third opening is a light-transmitting opening configured to increase the transmittance of light.

In an embodiment, in an optional implementation provided by this embodiment, the display panel further includes a transparent conductive connection portion 31, the transparent conductive connection portion 31 may be disposed between two adjacent first electrodes 21, the first electrode 21 is spaced apart from the transparent conductive connection portion 31, and the isolation structure 50 enclosing the third opening is connected to the transparent conductive connection portion 31. Here, the isolation structure 50 includes a conductive material and may provide a voltage for the transparent conductive connection portion 31 so that the transparent conductive connection portion 31 functions as a shield to prevent the upper layer's touch signal from interfering with the lower layer's drive signal and avoid problems such as poor touch control or display.

In an embodiment, the transparent conductive connection portion 31 and the auxiliary electrode 30 are disposed on the same layer, and the isolation structure 50 surrounding the third opening is connected to the transparent conductive connection portion 31.

In an embodiment, the transparent conductive connection portion 31 and the auxiliary electrode 30 are disposed on the same layer and are spaced apart to reduce the number of layers and help reduce the thickness of the display panel. In an embodiment, the material of the auxiliary electrode 30 includes a transparent conductive material. In an embodiment, The materials of the transparent conductive connection portion 31 and the auxiliary electrode 30 include indium tin oxide.

In an embodiment, the transparent conductive connection portion 31 is spaced apart from the auxiliary electrode 30. In an embodiment, the vertical projection of the transparent conductive connection portion 31 on the substrate 10 covers the vertical projection of the third opening on the substrate 10 to improve the shielding effect of the transparent conductive connection portion 31. The projection of the third opening refers to the vertical projection region of the opening space of the third opening enclosed by the isolation structure 50 on the substrate 10.

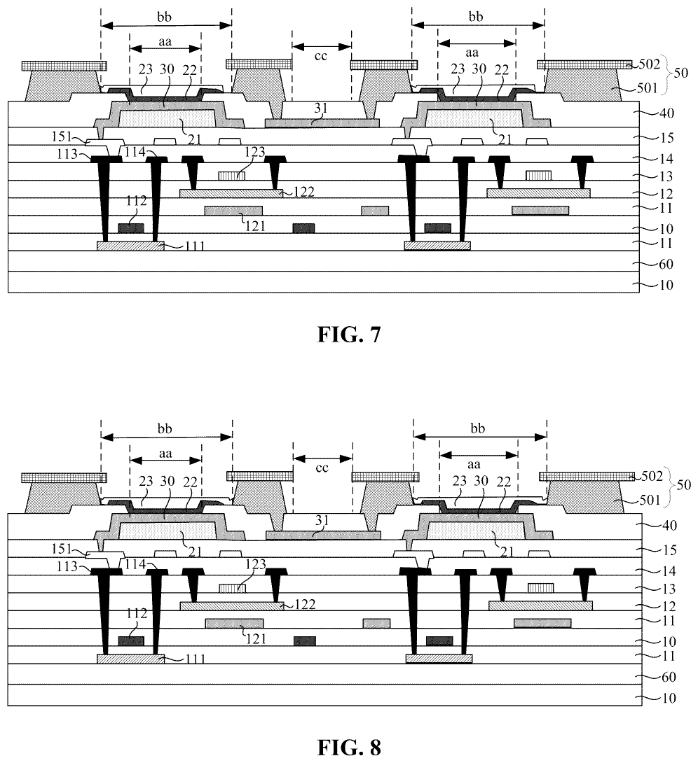

FIG. 7 is a diagram illustrating the structure of another display panel according to an embodiment of the present disclosure. With reference to FIG. 7, based on the preceding technical schemes, in an embodiment, the display panel further includes a light-emitting functional layer 22 and a second electrode 23; the light-emitting functional layer 22 is disposed on a side of the first electrode 21 facing away from the substrate 10, and the second electrode 23 is disposed on a side of the light-emitting functional layer 22 facing away from the substrate 10. The second electrode 23 is disposed in the first opening and the second opening. The stacked first electrode 21, the light-emitting functional layer 22, and the second electrode 23 together form a light-emitting element. Light-emitting elements of different colors correspond to different second electrodes 23, where the second electrode 23 may be a cathode. Each second electrode 23 is separated by the isolation structure 50. In an embodiment, isolation structures 50 corresponding to light-emitting elements of different colors may be spaced apart and insulated so that the second electrodes 23 corresponding to the light-emitting elements of different colors can be spaced apart and insulated to achieve individual control of each second electrode 23. The vertical projection of the light-emitting functional layer 22 on the substrate 10 and the vertical projection of the second electrode 23 on the substrate 10 are misaligned with the vertical projection of the third opening on the substrate 10, and the vertical projection of the third opening on the substrate 10 is misaligned with the vertical projection of the first opening on the substrate. In an embodiment, the vertical projection of the light-emitting functional layer 22 on the substrate 10 and the vertical projection of the second electrode 23 on the substrate do not overlap the vertical projection of the third opening on the substrate 10, and the vertical projection of the third opening on the substrate 10 does not overlap the vertical projection of the first opening on the substrate 10. That is, the light-emitting functional layer 22 and the second electrode 23 are not disposed in the third opening, and the third opening and the first opening are not connected to each other.

In an embodiment, with reference to FIG. 7, the light-emitting functional layer 22 in the display panel includes a first color light-emitting structure, a second color light-emitting structure, and a third color light-emitting structure, each color light-emitting structure corresponds to one pixel circuit, and different color light-emitting structures correspond to different pixel circuits. The first color light-emitting structure may emit red light. The second color light-emitting structure may emit green light. The third color light-emitting structure may emit blue light.

In this embodiment, the isolation structure 50 includes a conductive material. The support portion 501 may be metal or other conductive material. The crown portion 502 may be titanium. The second electrode 23 is in contact with at least part of the isolation structure 50 so that an electric signal is provided to the second electrode 23 through the isolation structure 50.

As shown in FIG. 7, the second electrode 23 is only in contact with the adjacent portion of the isolation structure 50 so that each second electrode 23 is insulated. In an example, when a first portion of the isolation structure 50 that encloses the third opening is connected to the transparent conductive connection portion 31, the first portion of the isolation structure 50 is not connected to the second electrode 23, and a second portion of the isolation structure 50 enclosing the second opening with the first portion of the isolation structure 50 is connected to the second electrode 23. Alternatively, in another example, when the first portion of the isolation structure 50 that encloses the third opening is connected to the transparent conductive connection portion 31, the first portion of the isolation structure 50 is connected to the second electrode 23, and a second portion of the isolation structure 50 enclosing the second opening with the first portion of the isolation structure 50 is not connected to the second electrode 23.

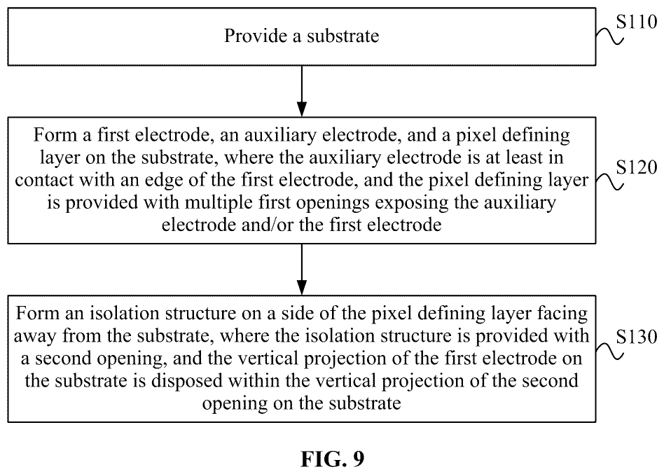

FIG. 8 is a diagram illustrating the structure of another display panel according to an embodiment of the present disclosure. With reference to FIG. 8, in an embodiment, the second electrode 23 may also be connected to each isolation structure 50 so that the second electrodes 23 corresponding to each pixel unit are connected together to form an integral conductive structure.

In this embodiment, since the first electrode 21 does not exist below the isolation structure 50, the isolation structure 50 has a relatively high flatness. Therefore, the side-etching accuracy of the support portion 501 can be improved, and the height and shape of the crown portion 502 can be ensured. Thus, when the isolation structure 50 and the second electrode 23 are overlapped and contacted, the reliability of the overlap and contact can be ensured, thereby preventing the phenomenon of weak overlap and contact and avoiding large-area dark spots.

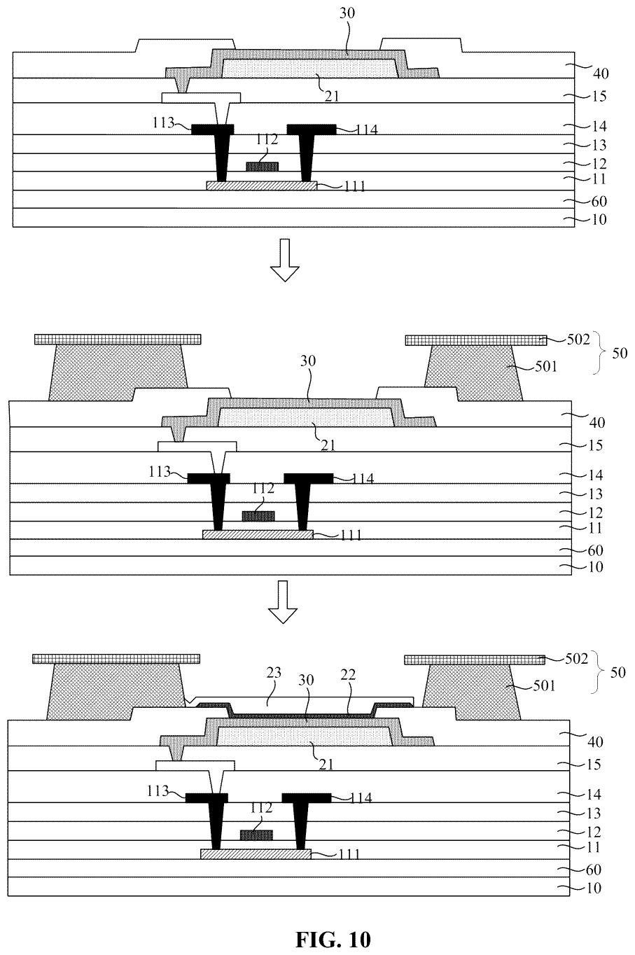

An embodiment of the present disclosure also provides a method for preparing a display panel. FIG. 9 is a flowchart of a method for preparing a display panel according to an embodiment of the present disclosure. FIG. 10 is a diagram illustrating the structure of a display panel formed by the main steps of the method for preparing a display panel according to an embodiment of the present disclosure. With reference to FIG. 9 and FIG. 10, the display panel provided in this embodiment includes the steps below.

In S110, a substrate is provided.

As shown in FIG. 10, the substrate 10 may be a rigid substrate or a flexible substrate to provide support.

In S120, a first electrode, an auxiliary electrode, and a pixel defining layer are formed on the substrate, where the auxiliary electrode is at least in contact with an edge of the first electrode, and the pixel defining layer is provided with multiple first openings exposing the auxiliary electrode and/or the first electrode.

In an embodiment, a first electrode 21, an auxiliary electrode 30, and a pixel defining layer 40 are formed in sequence on the substrate 10. The pixel defining layer 40 is configured to define a pixel region. The pixel defining layer 40 includes a first opening exposing the auxiliary electrode and/or the first electrode. The first electrode 21 and the auxiliary electrode 30 are in contact with each other and are used to transmit voltage signals.

Before the first electrode 21 is formed, a buffer layer 60, a first active layer 111, a first gate insulating layer 11, a first gate 112, a capacitive dielectric layer 12, a first interlayer insulating layer 13, a first source 114, a first drain 113, a first planarization layer 14, a transfer portion 151, and a second planarization layer 15 are also formed on the substrate. Certainly, a metal layer for transmitting a data signal and a power signal is disposed between the substrate 10 and the first electrode 21.

In S130, an isolation structure is formed on a side of the pixel defining layer facing away from the substrate, where the isolation structure is provided with a second opening, and the vertical projection of the first electrode on the substrate is disposed within the vertical projection of the second opening on the substrate.

In an embodiment, an isolation structure 50 is formed on a side of the pixel defining layer 40 facing away from the substrate 10. The isolation structure 50 may be used to isolate multiple pixel units to achieve individual control of different sub-pixels. Here, the isolation structure 50 encloses a second opening, and the second opening exposes the first opening and at least part of the pixel defining layer 40. The first electrode 21 is disposed in the second opening, that is, the first electrode 21 is disposed in an enclosed region of the isolation structure 50, and the vertical projection of the first electrode 21 on the substrate 10 does not overlap the vertical projection of the isolation structure 50 on the substrate 10. In other words, an edge of the first electrode 21 does not overlap the vertical projection of the isolation structure 50 on the substrate 10, and the first electrode 21 does not exist below the isolation structure 50 so that the flatness of the position of the pixel defining layer 40 corresponding to the isolation structure 50 can be improved. Moreover, when the isolation structure 50 is subsequently formed, the flatness of the isolation structure 50 can be improved.

In this embodiment, since the first electrode 21 is limited within the second opening enclosed by the isolation structure 50, the length of the first electrode 21 in the direction perpendicular to the thickness of the display panel is reduced. Moreover, the via used to connect the pixel circuit cannot be too close to the pixel region. Therefore, in order to ensure that the voltage signal is able to be transmitted to the first electrode 21, an auxiliary electrode 30 in this embodiment is disposed on a side of the first electrode 21 facing away from the substrate 10, and the auxiliary electrode 30 overlaps and contacts the first electrode 21 so that an electrical signal is transmitted to the first electrode 21 through the auxiliary electrode 30.

In the technical schemes provided by the embodiment of the present disclosure, the first electrode is limited within the second opening enclosed by the isolation structure, and an electrical signal is provided to the first electrode through the auxiliary electrode. In this manner, no edge of the first electrode exists under the isolation structure, thereby improving the flatness of the pixel defining layer and isolation structure, thus improving the overlapping and contacting effect between the isolation structure and the cathode in a light-emitting element, and preventing dark spots caused by poor overlapping and contacting. In addition, by limiting the first electrode, the gap in the pixel defining layer can be further reduced to prevent the occurrence of mixed colors or color spots.

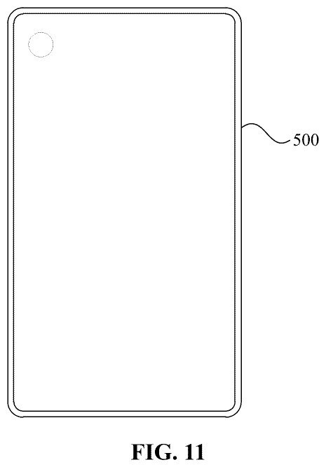

In an embodiment, an embodiment of the present disclosure also provides a display device. This display device includes the display panel provided by any embodiment of the present disclosure. FIG. 11 is a diagram illustrating the structure of a display device according to an embodiment of the present disclosure. The display device 500 may be not only the mobile phone shown in FIG. 11, but also an electronic device such as a tablet, a mobile phone, a watch, a wearable device, a car display, a camera display, a TV, and a computer screen. Since the display device includes the display panel provided by any embodiment of the present disclosure, the display device provided by the embodiment of the present disclosure also has the beneficial effects described in any embodiment of the present disclosure.

The preceding embodiments do not limit the scope of the present disclosure. It is to be understood by those skilled in the art that various modifications, combinations, sub-combinations, and substitutions may be performed according to design requirements and other factors. Any modifications, equivalent substitutions, improvements, and the like made within the spirit and principle of the present disclosure are within the scope of the present disclosure.

What is claimed is:

1. A display panel, comprising:
a substrate;
a first electrode, an auxiliary electrode, and a pixel defining layer, wherein the first electrode is disposed on a side of the substrate, the auxiliary electrode is at least in contact with an edge of the first electrode, and the auxiliary electrode is configured to provide an electrical signal to the first electrode; the pixel defining layer is provided with a plurality of first openings exposing at least one of the auxiliary electrode and the first electrode; and
an isolation structure disposed on a side of the pixel defining layer facing away from the substrate, wherein the isolation structure is provided with a second opening, and a vertical projection of the first electrode on the substrate is disposed within a vertical projection of the second opening on the substrate.

2. The display panel of claim 1, further comprising a light-emitting functional layer and a second electrode; wherein
the light-emitting functional layer is disposed on a side of the first electrode facing away from the substrate, the second electrode is disposed on a side of the light-emitting functional layer facing away from the substrate, and the second electrode is disposed in the first opening and the second opening;
the second electrode is in contact with at least part of the isolation structure.

3. The display panel of claim 2, wherein second electrodes corresponding to light-emitting functional layers of different colors are spaced apart and insulated from each other.

4. The display panel of claim 1, wherein the second opening is connected to the first opening, and the second opening exposes at least part of the pixel defining layer.

5. The display panel of claim 1, wherein the auxiliary electrode is disposed on a side of the first electrode facing away from the substrate.

6. The display panel of claim 1, wherein the pixel defining layer comprises an inorganic material.

7. The display panel of claim 1, wherein a vertical projection of the auxiliary electrode on the substrate covers the vertical projection of the first electrode on the substrate, and the first opening exposes the auxiliary electrode.

8. The display panel of claim 7, wherein the display panel further comprises a plurality of pixel circuits, a pixel circuit of the plurality of pixel circuits is disposed on a side of the first electrode facing the substrate, and the auxiliary electrode is connected to the pixel circuit.

9. The display panel of claim 7, wherein a vertical projection of the pixel defining layer on the substrate partially overlaps the vertical projection of the first electrode on the substrate.

10. The display panel of claim 8, wherein the vertical projection of the auxiliary electrode on the substrate partially overlaps a vertical projection of the isolation structure on the substrate; and
the auxiliary electrode comprises an overlapping portion overlapping the isolation structure, and the overlapping portion of the auxiliary electrode is connected to the pixel circuit through a via.

11. The display panel of claim 1, wherein in a thickness direction of the display panel, a thickness of the auxiliary electrode is less than a thickness of the first electrode.

12. The display panel of claim 11, wherein in a thickness direction of the display panel, the thickness of the auxiliary electrode is greater than or equal to 0.01 μm and less than or equal to 0.1 μm;
in a plane parallel to the substrate, a width of a portion of the pixel defining layer disposed between two adjacent first openings is greater than or equal to 8 μm.

13. The display panel of claim 2, wherein the isolation structure comprises a conductive material;
a vertical projection of a surface of the isolation structure facing a side of the substrate on the substrate is disposed within a vertical projection of a surface of the isolation structure facing away from the side of the substrate on the substrate;
the isolation structure comprises a support portion and a crown portion, the crown portion is disposed on a side of the support portion facing away from the substrate, and a vertical projection of the support portion on the substrate is disposed within a vertical projection of the crown portion on the substrate.

14. The display panel of claim 13, wherein the vertical projection of the support portion on the substrate does not overlap the vertical projection of the first electrode on the substrate;
the vertical projection of the crown portion on the substrate does not overlap the vertical projection of the first electrode on the substrate; and
the second electrode is electrically connected to the isolation structure.

15. The display panel of claim 2, wherein the isolation structure is further provided with a third opening exposing the pixel defining layer, and the second opening is spaced apart from the third opening.

16. The display panel of claim 15, wherein a material of the auxiliary electrode comprises a transparent conductive material;
the display panel further comprises a transparent conductive connection portion disposed on a same layer as the auxiliary electrode, and the isolation structure surrounding the third opening is connected to the transparent conductive connection portion.

17. The display panel of claim 16, wherein the transparent conductive connection portion is spaced apart from the auxiliary electrode, and a vertical projection of the transparent conductive connection portion on the substrate covers a vertical projection of the third opening on the substrate;
the material of the auxiliary electrode and a material of the transparent conductive connection portion comprise indium tin oxide.

18. The display panel of claim 16, wherein the first electrode is spaced apart from the transparent conductive connection portion; and
a vertical projection of the light-emitting functional layer on the substrate and a vertical projection of the second electrode on the substrate are misaligned with the vertical projection of the third opening on the substrate, and the vertical projection of the third opening on the substrate is misaligned with a vertical projection of the first opening on the substrate.

19. A method for preparing a display panel, comprising:
providing a substrate;
forming a first electrode, an auxiliary electrode, and a pixel defining layer on the substrate; wherein the auxiliary electrode is at least in contact with an edge of the first electrode, and the pixel defining layer is provided with a plurality of first openings exposing at least one of the auxiliary electrode and the first electrode; and
forming an isolation structure on a side of the pixel defining layer facing away from the substrate; wherein the isolation structure is provided with a second opening, and a vertical projection of the first electrode on the substrate is disposed within a vertical projection of the second opening on the substrate.

20. A display device, comprising the display panel of claim 1.
